(19) United States
(12) Patent Application Publication
(10) Pub. No.: US 2019/0306982 A1
(43) Pub. Date: Oct. 3, 2019

(54) CIRCUIT BOARD AND METHOD OF MANUFACTURING CIRCUIT BOARD

(71) Applicant: FUJITSU LIMITED, Kawasaki-shi (JP)

(72) Inventors: Hideaki Nagaoka, Atsugi (JP); Tomoyuki AKAHOSHI, Atsugi (JP); Daisuke Mizutani, Sagamihara (JP)

(73) Assignee: FUJITSU LIMITED, Kawasaki-shi (JP)

(21) Appl. No.: 16/270,634

(22) Filed: Feb. 8, 2019

(30) Foreign Application Priority Data
Mar. 28, 2018 (JP) 2018-061451

(51) Int. Cl. H05K 1/16; H05K 1/11; H05K 3/42; H05K 3/40; H01G 4/12; H01G 4/008; H05K 1/02; H05K 1/18; H05K 3/02; H05K 3/06; H05K 3/00; H01G 4/33

(52) U.S. Cl. CPC H05K 1/162; H05K 2203/072; H05K 3/429; H05K 3/4007; H01G 4/1227; H01G 4/008; H05K 1/0271; H05K 1/165; H05K 1/186; H05K 3/027; H05K 3/06; H05K 3/0032; H05K 3/422; H01G 4/33; H05K 2203/107; H05K 1/113

(57) ABSTRACT

A circuit board includes an insulator layer, an electronic component built into the insulator layer, a first via penetrating the insulator layer, a second via extending from one surface of the insulator layer and coupled to the electronic component, and a metal layer formed over the one surface of the insulator layer, wherein a via pad is formed over the second via, an opening is formed between the metal layer and a first via side of the via pad, and the opposite side of the via pad to the first via side is coupled to the metal layer.

### CROSS-REFERENCE TO RELATED APPLICATION

This application is based upon and claims the benefit of priority of the prior Japanese Patent Application No. 2018-61451, filed on Mar. 28, 2018, the entire contents of which are incorporated herein by reference.

### FIELD

The embodiments discussed herein are related to a circuit board and a method of manufacturing a circuit board.

### BACKGROUND

Along with miniaturization and high functionality of electronics, there have recently been increasing densification and miniaturization of active element components such as an integrated circuit (IC) mounted on a printed-wiring circuit board as well as passive element components such as a capacitor, a resistor, and an inductor. Although the circuit board has been fabricated so far by densely mounting small active element components and passive element components, there have been conducted studies on building such components into a circuit board, in order to meet a demand for further miniaturization. When such active element components and passive element components are built into the circuit board, not only miniaturization but also improvement in reliability as well as improvement in electrical characteristics by reducing parasitic resistance, parasitic capacity, and the like are also expected because of reduction in soldered joints and shortened wiring.

As a circuit board having built-in passive element components, disclosed is one having a built-in thin-film capacitor having a structure in which both surfaces of a ferroelectric layer are sandwiched between electrode layers. In this way, by building the thin-film capacitor into the circuit board, the distance between the IC and the capacitor may be shortened.

However, in the case of using a circuit board in which electronic components such as active element components and passive element components are built, these electronic components, other components, and the like may generate heat, and the generated heat may cause distortion in the circuit board and damage the circuit board.

Therefore, there has been a demand for a highly reliable circuit board having built-in electronic components.

The followings are reference documents.
[Document 1] Japanese Laid-open Patent Publication No. 2006-210776,
[Document 2] Japanese Laid-open Patent Publication No. 2015-18988,
[Document 3] Japanese Laid-open Patent Publication No. 2017-112236, and
[Document 4] Japanese Laid-open Patent Publication No. 2017-208369.

### SUMMARY

According to an aspect of the embodiments, a circuit board includes an insulator layer, an electronic component built into the insulator layer, a first via penetrating the insulator layer, a second via extending from one surface of the insulator layer and coupled to the electronic component, and a metal layer formed over the one surface of the insulator layer, wherein a via pad is formed over the second via, an opening is formed between the metal layer and a first via side of the via pad, and the opposite side of the via pad to the first via side is coupled to the metal layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a structural diagram of a circuit board having built-in electronic components;

FIG. 2 is a structural diagram of a circuit board according to a first embodiment;

FIG. 3 is an explanatory diagram (1) illustrating simulation in a circuit board having built-in electronic components;

FIG. 4 is an explanatory diagram (2) illustrating simulation in the circuit board having built-in electronic components;

FIG. 5 is an explanatory diagram (3) illustrating simulation in the circuit board having built-in electronic components;

FIG. 6 is an explanatory diagram (4) illustrating simulation in the circuit board having built-in electronic components;

FIG. 7 is an explanatory diagram (1) illustrating simulation in the circuit board according to the first embodiment;

FIG. 8 is an explanatory diagram (2) illustrating simulation in the circuit board according to the first embodiment;

FIG. 9 is an explanatory diagram (3) illustrating simulation in the circuit board according to the first embodiment;

FIG. 10 is an explanatory diagram (4) illustrating simulation in the circuit board according to the first embodiment;

FIG. 11 is an explanatory diagram (5) illustrating simulation in the circuit board according to the first embodiment;

FIG. 12 is an explanatory diagram (6) illustrating simulation in the circuit board according to the first embodiment;

FIG. 13 is a structural diagram illustrating modified example 1 of the circuit board according to the first embodiment;

FIG. 14 is a structural diagram illustrating modified example 2 of the circuit board according to the first embodiment;

FIG. 15 is a structural diagram illustrating modified example 3 of the circuit board according to the first embodiment;

FIG. 16 is a structural diagram of a circuit board according to a second embodiment;

FIG. 17 is an explanatory diagram (1) illustrating simulation in the circuit board according to the second embodiment;

FIG. 18 is an explanatory diagram (2) illustrating simulation in the circuit board according to the second embodiment;

FIGS. 19A and 19B are diagrams (1) illustrating a step of a method of manufacturing a circuit board according to the second embodiment;

FIGS. 20A and 20B are diagrams (2) illustrating a step of the method of manufacturing a circuit board according to the second embodiment;

FIGS. 21A and 21B are diagrams (3) illustrating a step of the method of manufacturing a circuit board according to the second embodiment;

FIGS. 22A and 22B are diagrams (4) illustrating a step of the method of manufacturing a circuit board according to the second embodiment;

FIGS. 23A and 23B are diagrams (5) illustrating a step of the method of manufacturing a circuit board according to the second embodiment; and

FIG. 24 is a diagram (6) illustrating a step of the method of manufacturing a circuit board according to the second embodiment.

### DESCRIPTION OF EMBODIMENTS

Hereinafter, embodiments are described. The same components and the like are denoted by the same reference numerals, and are not elaborated upon repeatedly. In the present application, an X1-X2 direction, a Y1-Y2 direction, and a Z1-Z2 direction are perpendicular to each other. A plane including the X1-X2 direction and the Y1-Y2 direction is expressed as an XY-plane, a plane including the Y1-Y2 direction and the Z1-Z2 direction is expressed as a YZ-plane, and a plane including the Z1-Z2 direction and the X1-X2 direction is expressed as a ZX-plane.

### First Embodiment

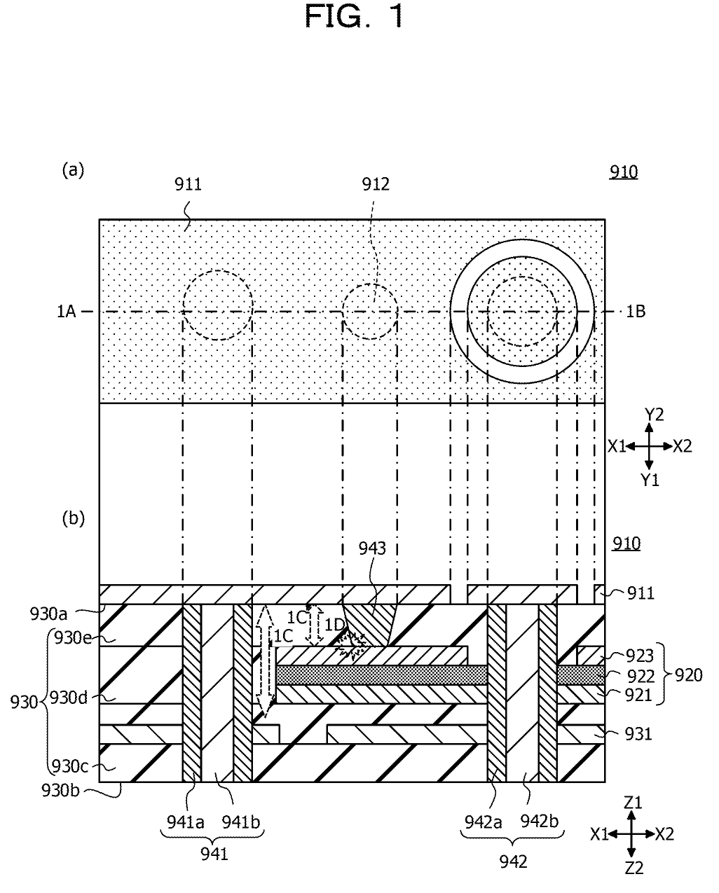

First, with reference to FIG. 1, description is given of a circuit board having a built-in capacitor as a passive element component. A circuit board 910 illustrated in FIG. 1 has a thin-film capacitor 920 formed inside the circuit board 910, that is, is a circuit board having the thin-film capacitor 920 as the passive element component built therein. FIG. 1(a) is a top view of the circuit board 910, while FIG. 1(b) is a cross-sectional view taken along the dashed line IA-IB. In the circuit board 910, an insulator layer 930 is formed by sequentially stacking a first build-up resin layer 930d and a second build-up resin layer 930e on a core resin layer 930c, and the thin-film capacitor 920 is formed inside the insulator layer 930. The thin-film capacitor 920 is formed by stacking a lower electrode layer 921, a ferroelectric layer 922, and an upper electrode layer 923 on the first build-up resin layer 930d, and is covered with the second build-up resin layer 930e. Thus, the ferroelectric layer 922 is sandwiched between the lower electrode layer 921 and the upper electrode layer 923. The lower electrode layer 921 and the upper electrode layer 923 serve as electrodes of the thin-film capacitor 920.

This circuit board 910 has a metal layer 911 formed on one surface 930a of the insulator layer 930. The circuit board 910 also has two through-holes formed therein, which penetrate from one surface 930a to the other surface 930b of the insulator layer 930. Inside the through-holes, through-hole vias 941 and 942 are formed. The through-hole via 941 includes a penetrating electrode layer 941a formed on the inside of the through-hole and a filler resin 941b formed on the inner side of the penetrating electrode layer 941a. Likewise, the through-hole via 942 includes a penetrating electrode layer 942a formed on the inside of the through-hole and a filler resin 942b formed on the inner side of the penetrating electrode layer 942a.

In the circuit board 910, the front and back sides of the circuit board 910 are electrically connected to each other by the penetrating electrode layer 941a of the through-hole via 941 and the penetrating electrode layer 942a of the through-hole via 942. The circuit board 910 also has an interlayer via 943 formed therein to connect the upper electrode layer 923 of the thin-film capacitor 920 to the metal layer 911 formed on the one surface 930a of the insulator layer 930.

In the circuit board 910, the lower electrode layer 921, the penetrating electrode layers 941a and 942a of the through-hole vias 941 and 942, the interlayer via 943, and the like are formed of copper (Cu) or the like, while the upper electrode layer 923 is formed of nickel (Ni). The insulator layer 930 is formed of glass epoxy resin, while the ferroelectric layer 922 of the thin-film capacitor 920 is formed of barium strontium titanate.

Copper has a thermal expansion coefficient of about 16.8 ppm/° C. and a Young's modulus of about 110 GPa. Nickel has a thermal expansion coefficient of about 13.4 ppm/° C. and a Young's modulus of about 200 GPa. Barium strontium titanate has a thermal expansion coefficient of about 9.6 ppm/° C. and a Young's modulus of about 180 GPa. A thermal expansion coefficient of glass epoxy resin is about 15 ppm/° C. in a plane direction, is about 45 ppm/° C. up to 175° C. that is a glass-transition temperature in a thickness direction, and gets to about 240 ppm/° C. over 175° C. Glass epoxy resin has a Young's modulus of about 25 GPa.

Therefore, the material used to form the lower electrode layer 921, the upper electrode layer 923, the penetrating electrode layers 941a and 942a of the through-hole vias 941 and 942, and the interlayer via 943 is significantly different in thermal expansion coefficient from the material used to form the insulator layer 930. For this reason, when the thin-film capacitor 920 and the like generate heat or heat is applied to the entire circuit board 910, stress is generated by a difference in thermal expansion coefficient between the materials used to form the respective components. This stress may damage some part of the circuit board 910.

For example, glass epoxy resin used to form the insulator layer 930 has a larger thermal expansion coefficient in the Z1-Z2 direction that is the thickness direction, compared with other portions thereof. When heat is applied to the circuit board 910, the circuit board 910 expands significantly in the Z1-Z2 direction as indicated by the broken arrows 1C. Such thermal expansion may concentrate stress in a portion in contact with the insulator layer 930 that is a connection portion between the thin-film capacitor 920 and the interlayer via 943, for example, and may damage this portion, as indicated by the broken line 1D, and thus the circuit board 910.

### Circuit Board

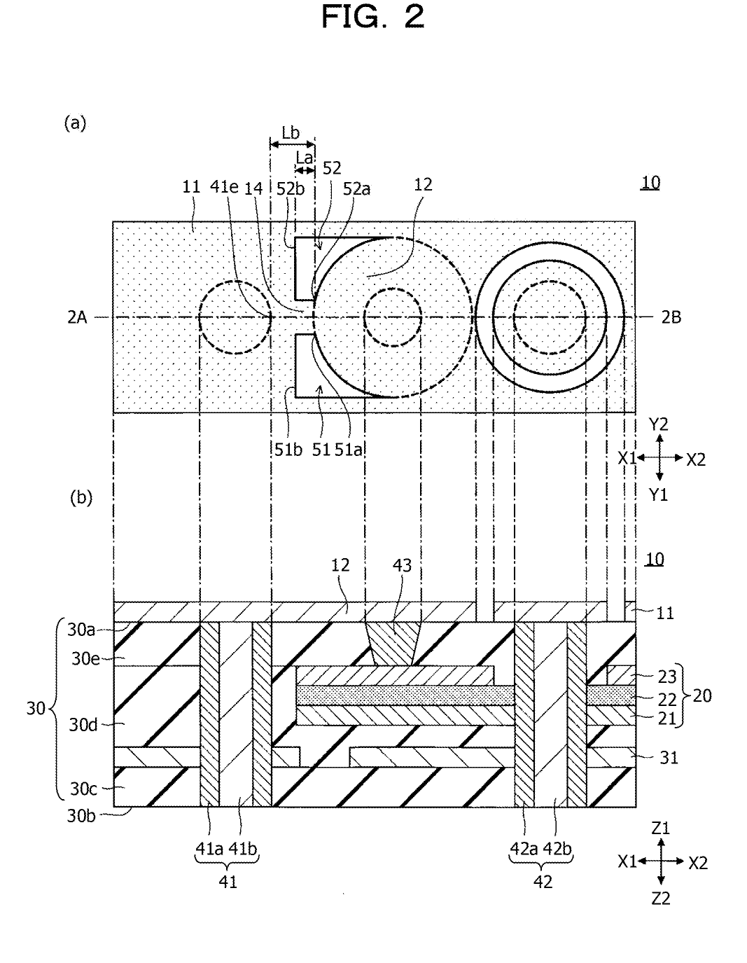

Next, with reference to FIG. 2, description is given of a circuit board having a built-in capacitor as a passive element component according to this embodiment. As illustrated in FIG. 2, a circuit board 10 according to this embodiment has a thin-film capacitor 20 formed inside the circuit board 10, that is, is a circuit board having the thin-film capacitor 20 as the passive element component built therein. FIG. 2(a) is a top view of the circuit board 10, while FIG. 2(b) is a cross-sectional view taken along the dashed line IIA-IIB.

In the circuit board 10, an insulator layer 30 is formed by sequentially stacking a first build-up resin layer 30d and a second build-up resin layer 30e on a core resin layer 30c, and the thin-film capacitor 20 is formed inside the insulator layer 30. The thin-film capacitor 20 is formed by stacking a lower electrode layer 21, a ferroelectric layer 22, and an upper electrode layer 23 on the first build-up resin layer 30d, and is covered with the second build-up resin layer 30e. Thus, the ferroelectric layer 22 is sandwiched between the lower electrode layer 21 and the upper electrode layer 23. The lower electrode layer 21 and the upper electrode layer 23 serve as electrodes of the thin-film capacitor 20.

This circuit board 10 has a metal layer 11 formed on one surface 30a of the insulator layer 30. The circuit board 10 also has two through-holes formed therein, which penetrate from one surface 30a to the other surface 30b of the insulator layer 30. Inside the through-holes, through-hole vias 41 and 42 are formed. The through-hole via 41 includes a penetrating electrode layer 41a formed on the inside of the through-hole and a filler resin 41b formed on the inner side of the penetrating electrode layer 41a. Likewise, the through-hole via 42 includes a penetrating electrode layer 42a formed on the inside of the through-hole and a filler resin 42b formed on the inner side of the penetrating electrode layer 42a.

In the circuit board 10, the front and back sides of the circuit board 10 are electrically connected to each other by the penetrating electrode layer 41a of the through-hole via 41 and the penetrating electrode layer 42a of the through-hole via 42. The circuit board 10 also has an interlayer via 43 formed therein to connect the upper electrode layer 23 of the thin-film capacitor 20 to the metal layer 11 formed on the one surface 30a of the insulator layer 30.

In the circuit board 10, the lower electrode layer 21, the penetrating electrode layers 41a and 42a of the through-hole vias 41 and 42, the interlayer via 43, and the like are formed of copper (Cu) or the like, while the upper electrode layer 23 is formed of nickel (Ni). The insulator layer 30 is formed of glass epoxy resin, while the ferroelectric layer 22 of the thin-film capacitor 20 is formed of barium strontium titanate. In the present application, the through-hole via 41 may be described as a first via and the interlayer via 43 as a second via.

In the circuit board 10 according to this embodiment, in order to relax stress, openings 51 and 52 are formed in the metal layer 11 on the one surface 30a of the insulator layer 30. For example, an interlayer via pad 12 larger than the interlayer via 43 is formed on the interlayer via 43, and the openings 51 and 52 are formed between the interlayer via pad 12 and the through-hole via 41 on the X1 side of the interlayer via pad 12.

For example, on the X2 side of the interlayer via pad 12, the interlayer via pad 12 is connected to and integrated with the metal layer 11. On the X1 side of the interlayer via pad 12, a connector 14 extending in the X1-X2 direction connects the interlayer via pad 12 to the metal layer 11, and the openings 51 and 52 are formed in the metal layer 11 on both sides thereof. The interlayer via pad 12 and the connector 14 are made of the same material and have the same thickness as the metal layer 11.

The interlayer via pad 12 is formed in a circular shape with a diameter of about 100 μm. On the X1 side of the interlayer via pad 12, the connector 14 connecting the interlayer via pad 12 to the metal layer 11 has a width of 30 μm in the Y1-Y2 direction. On the X1 side of the interlayer via pad 12, the opening 51 is formed on the Y1 side of the connector 14, while the opening 52 is formed on the Y2 side of the connector 14.

The opening 51 is a region surrounded by a tangent to the interlayer via pad 12 on the Y1 side, which is parallel to the X1-X2 direction on the Y1 side, a part of the circumference of the interlayer via pad 12 on the X2 side, the connector 14 on the Y2 side, and an end portion 51b on the X1 side, which is parallel to the Y1-Y2 direction. The opening 52 is a region surrounded by a tangent to the interlayer via pad 12 on the Y2 side, which is parallel to the X1-X2 direction on the Y2 side, a part of the circumference of the interlayer via pad 12 on the X2 side, the connector 14 on the Y1 side, and an end portion 52b on the X1 side, which is parallel to the Y1-Y2 direction.

It is assumed in the present application that a length from positions 51a and 52a of the openings 51 and 52 where the interlayer via pad 12 and the connector 14 come into contact with each other to the end portions 51b and 52b on the X1 side is an interlayer via pad-opening end distance La. It is also assumed that a length from the positions 51a and 52a where the interlayer via pad 12 and the connector 14 come into contact with each other to the end of the through-hole via 41 on the X1 side is an interlayer via pad-through-hole via end distance Lb.

In the circuit board 10 according to this embodiment, stress is relaxed by the openings 51 and 52 formed in the metal layer 11 even when the insulator layer 30 is thermally expanded. Therefore, stress on the insulator layer 30 side between the thin-film capacitor 20 and the interlayer via 43 is also relaxed. Thus, the circuit board 10 may be suppressed from being damaged.

### Simulation

Next, description is given of simulation conducted by the inventor concerning stress when heat is applied to a circuit board.

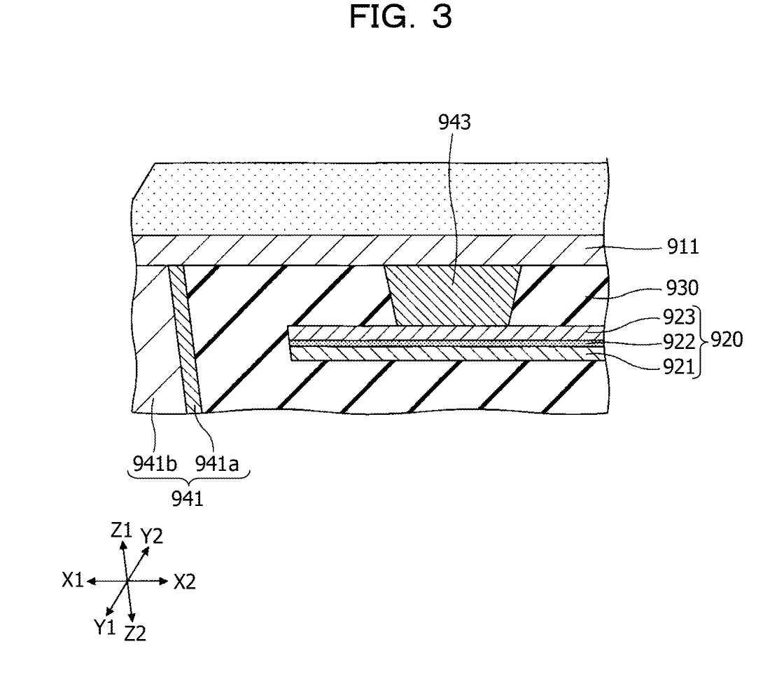

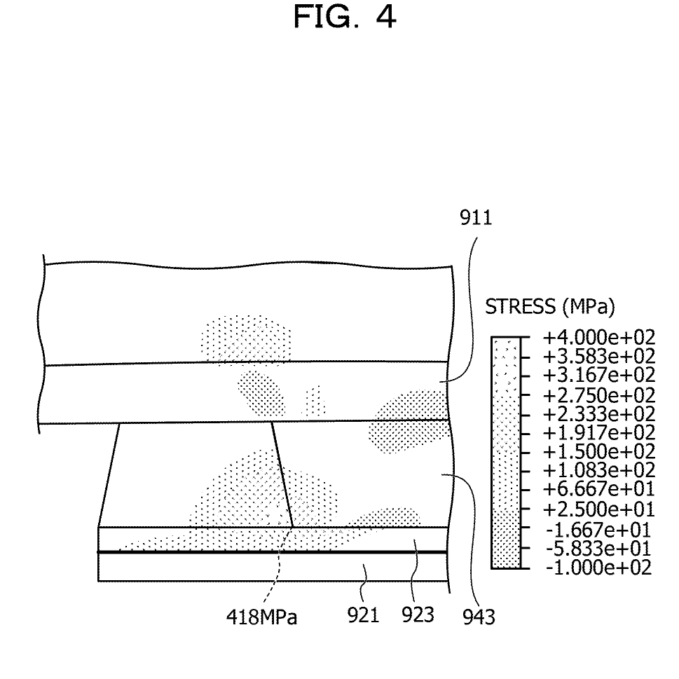

First, FIG. 4 illustrates a result of simulation conducted on a circuit board model having a structure illustrated in FIG. 3, as a model of the circuit board 910 having the structure illustrated in FIG. 1. The model having the structure illustrated in FIG. 3 serves as a part of the circuit board 910 illustrated in FIG. 1, and has the filler resin 941b filled inside the penetrating electrode layer 941a of the through-hole via 941 formed of metal. The material used to form the filler resin 941b has a thermal expansion coefficient of about 32 ppm/° C. up to 160° C. that is a glass-transition temperature and about 83 ppm/° C. over 160° C., and also has a Young's modulus of about 86 GPa.

In the circuit board model illustrated in FIG. 3, an interlayer via 943 is formed on a thin-film capacitor 920 including a lower electrode layer 921, a ferroelectric layer 922, and an upper electrode layer 923. The interlayer via 943 is formed on a part of the upper electrode layer 923 of the thin-film capacitor 920, and is electrically connected to the upper electrode layer 923. An insulator layer 930 is formed in a region on the upper electrode layer 923 where the interlayer via 943 is not formed, and the interlayer via 943 is surrounded by the insulator layer 930. A metal layer 911 is formed on the entire surface on the interlayer via 943 and the insulator layer 930.

As for the thin-film capacitor 920, the lower electrode layer 921 has a film thickness of about 30 μm, the ferroelectric layer 922 has a film thickness of about 1 μμm, and the upper electrode layer 923 has a film thickness of about 30 μm. The interlayer via 943 is formed so as to have a diameter of about 50 μm on the thin-film capacitor 920 side and a diameter of about 60 μm on the metal layer 911 side. The interlayer via 943 and the insulator layer 930 on the upper electrode layer 923 have a film thickness of about 50 μμm. The metal layer 911 has a thickness of about 30 μm.

In this circuit board model, when the temperature is raised from 25° C. to 250° C., stress is concentrated in a portion in contact with the insulator layer 930 that is a connection portion between the thin-film capacitor 920 and the interlayer via 943, as illustrated in FIG. 4, and a stress value in this portion is 418 MPa.

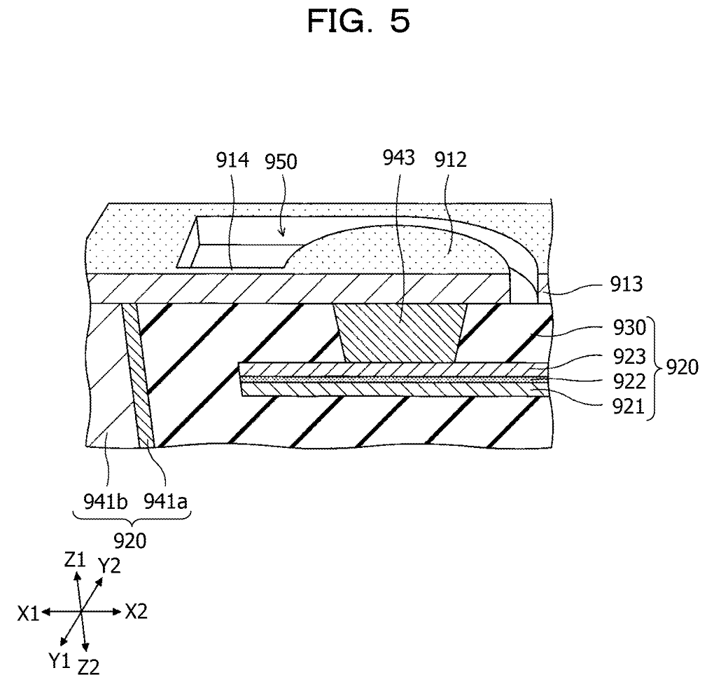

Next, simulation is conducted on a circuit board model illustrated in FIG. 5. In the circuit board model illustrated in FIG. 5, an interlayer via pad 912 is formed above an interlayer via 943, a conductor opening 950 is formed around the interlayer via pad 912, and a metal layer 913 is formed around the conductor opening 950. The metal layer 913 and the interlayer via pad 912 are connected to each other by a connector 914 extending in the X1-X2 direction. The interlayer via pad 912, the metal layer 913, and the connector 914 are made of the same material and have the same thickness as the metal layer 911.

Therefore, the conductor opening 950 is formed between the interlayer via pad 912 and the metal layer 913, and is formed in the Y1 direction, Y2 direction, and X2 direction around the interlayer via pad 912, except for the connector 914 in the X1 direction. The interlayer via pad 912 is formed in a circular shape with a diameter of about 100 μm. The conductor opening 950 is formed to have a width of about 25 μm on the X2 side of the interlayer via pad 912, and to have a larger width on the X1 side.

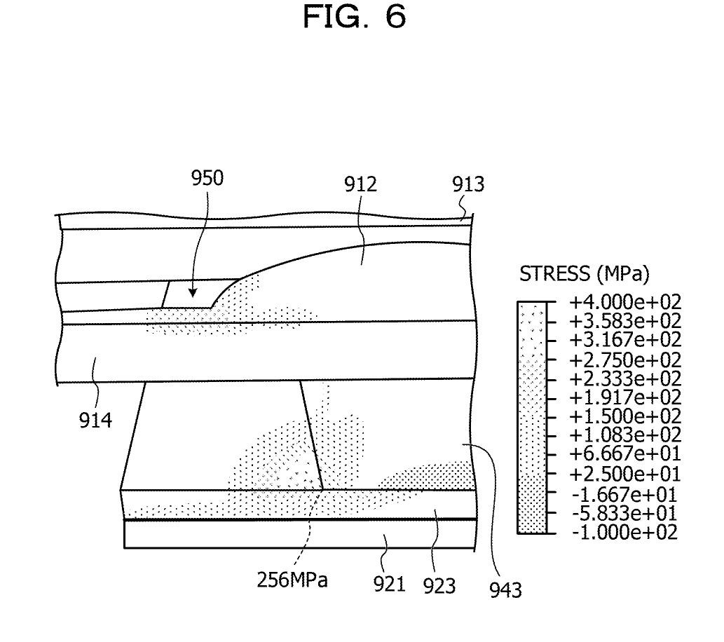

In this circuit board model, when the temperature is raised from 25° C. to 250° C., stress is concentrated in a portion in contact with the insulator layer 930 that is a connection portion between the thin-film capacitor 920 and the interlayer via 943, as illustrated in FIG. 6, and a stress value in this portion is 256 MPa. Therefore, some stress concentration is relaxed by forming the conductor opening 950, which is, however, not sufficient.

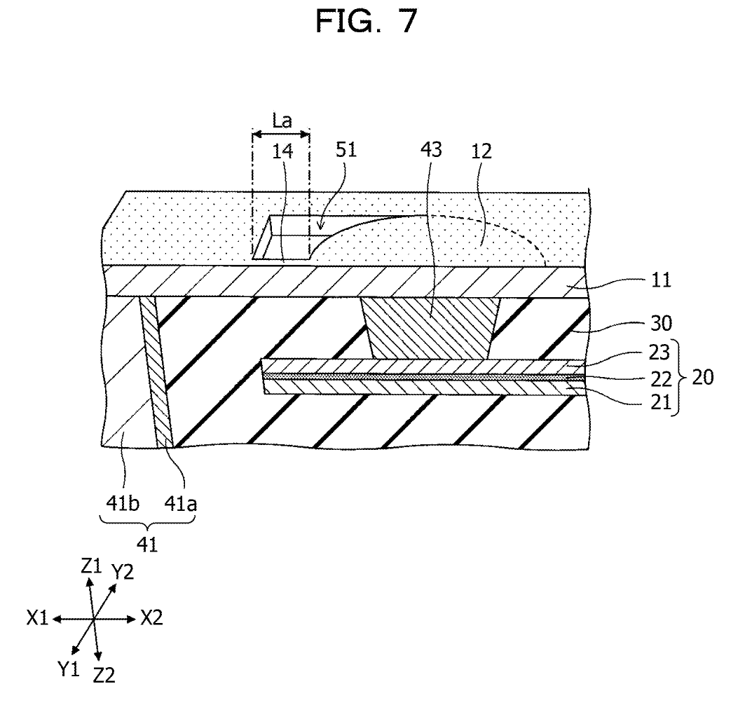

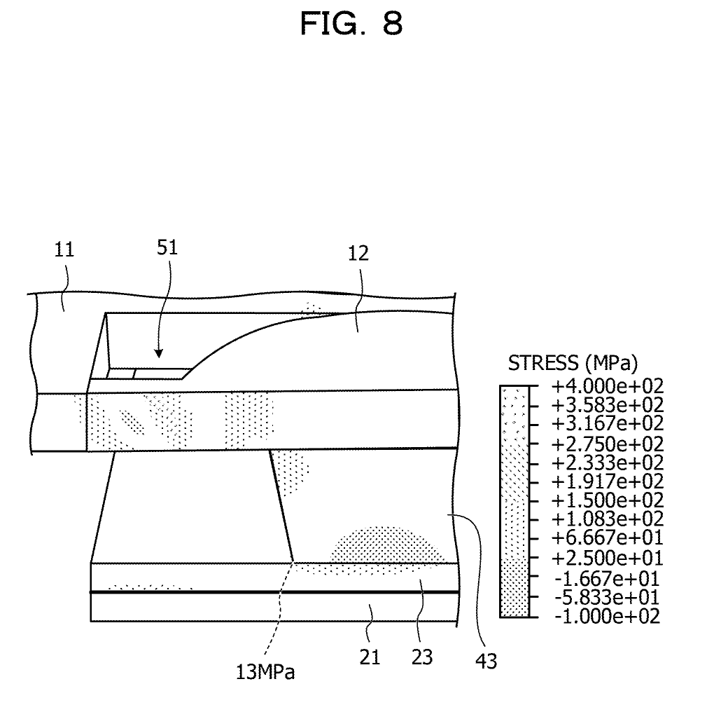

Next, FIG. 8 illustrates a result of simulation conducted on a circuit board model having a structure illustrated in FIG. 7, as a model of the circuit board 10 according to this embodiment illustrated in FIG. 2. The model having the structure illustrated in FIG. 7 serves as a part of the circuit board 10 according to this embodiment illustrated in FIG. 2, and has the filler resin 41b filled inside the penetrating electrode layer 41a of the through-hole via 41 formed of metal. The material used to form the filler resin 41b has a thermal expansion coefficient of about 32 ppm/° C. up to 160° C. that is a glass-transition temperature and about 83 ppm/° C. over 160° C., and also has a Young's modulus of about 86 GPa.

In the circuit board model illustrated in FIG. 7, an interlayer via 43 is formed on a thin-film capacitor 20 including a lower electrode layer 21, a ferroelectric layer 22, and an upper electrode layer 23. The interlayer via 43 is formed on a part of the upper electrode layer 23 of the thin-film capacitor 20, and is electrically connected to the upper electrode layer 23. An insulator layer 30 is formed in a region on the upper electrode layer 23 where the interlayer via 43 is not formed, and the interlayer via 43 is surrounded by the insulator layer 30. On the interlayer via 43, an interlayer via pad 12 is formed in an approximately circular shape with a diameter of 100 μm, which is larger than the interlayer via 43. The interlayer via pad 12 is in contact and integrated with the metal layer 11 on the X2 side, and is connected to the metal layer 11 by a connector 14 on the X1 side. Between the X1 side of the interlayer via pad 12 and the metal layer 11, an opening 51 is formed on the Y1 side and an opening 52 is formed on the Y2 side.

As for the thin-film capacitor 20, the lower electrode layer 21 has a film thickness of about 30 μm, the ferroelectric layer 22 has a film thickness of about 1 μm, and the upper electrode layer 23 has a film thickness of about 30 μm. The interlayer via 43 is formed so as to have a diameter of about 50 μm on the thin-film capacitor 20 side and a diameter of about 60 μm on the metal layer 11 side. The interlayer via 43 and the insulator layer 30 on the upper electrode layer 23 have a film thickness of about 50 μm. The metal layer 11 has a thickness of about 30 μm. An interlayer via pad-opening end distance La is 45 μm.

In the circuit board model illustrated in FIG. 7, when the temperature is raised from 25° C. to 250° C., a portion in contact with the insulator layer 30 that is a connection portion between the thin-film capacitor 20 and the interlayer via 43 has a stress value of 13 MPa as illustrated in FIG. 8.

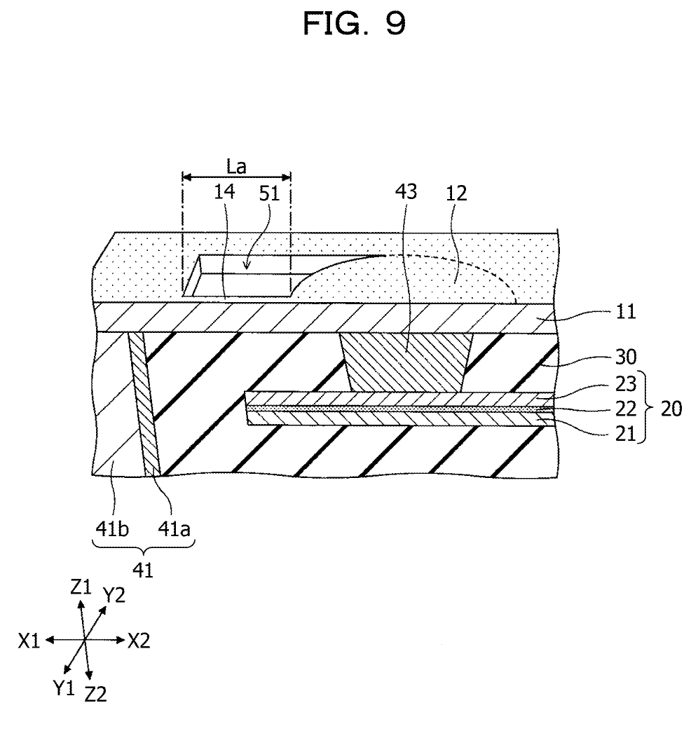

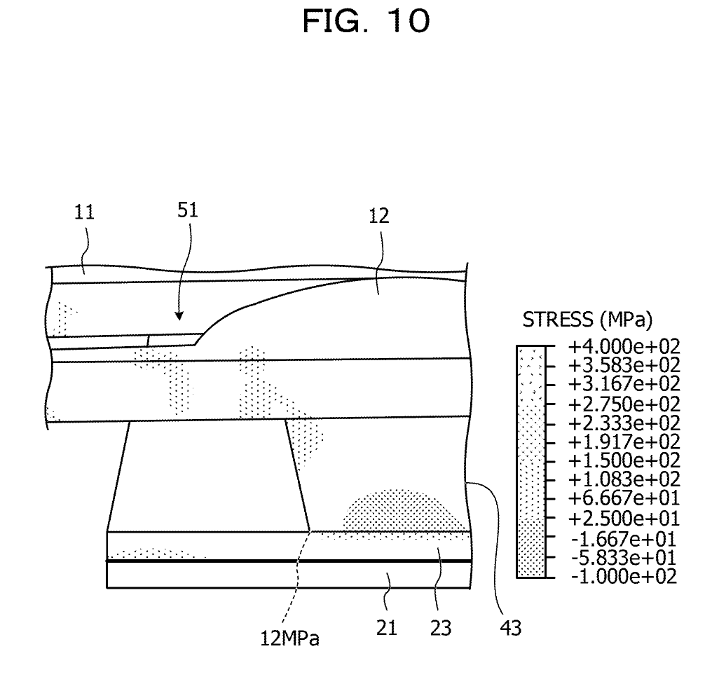

Next, FIG. 10 illustrates a result of simulation conducted on a circuit board model having a structure illustrated in FIG. 9, as a model of the circuit board 10 according to this embodiment illustrated in FIG. 2. The model having the structure illustrated in FIG. 9 is a part of the circuit board 10 according to this embodiment illustrated in FIG. 2, and an interlayer via pad-opening end distance La is set to 88 μm.

In the circuit board model illustrated in FIG. 9, when the temperature is raised from 25° C. to 250° C., a portion in contact with the insulator layer 30 that is a connection portion between the thin-film capacitor 20 and the interlayer via 43 has a stress value of 12 MPa as illustrated in FIG. 10.

As described above, in the circuit board of this embodiment, stress in the portion in contact with the insulator layer 30 that is the connection portion between the thin-film capacitor 20 and the interlayer via 43 may be reduced even when the temperature of the circuit board is increased.

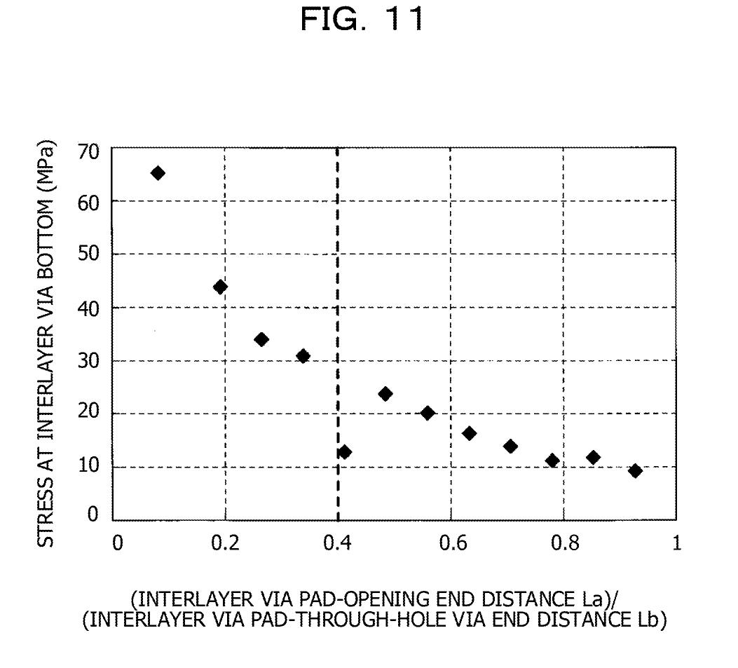

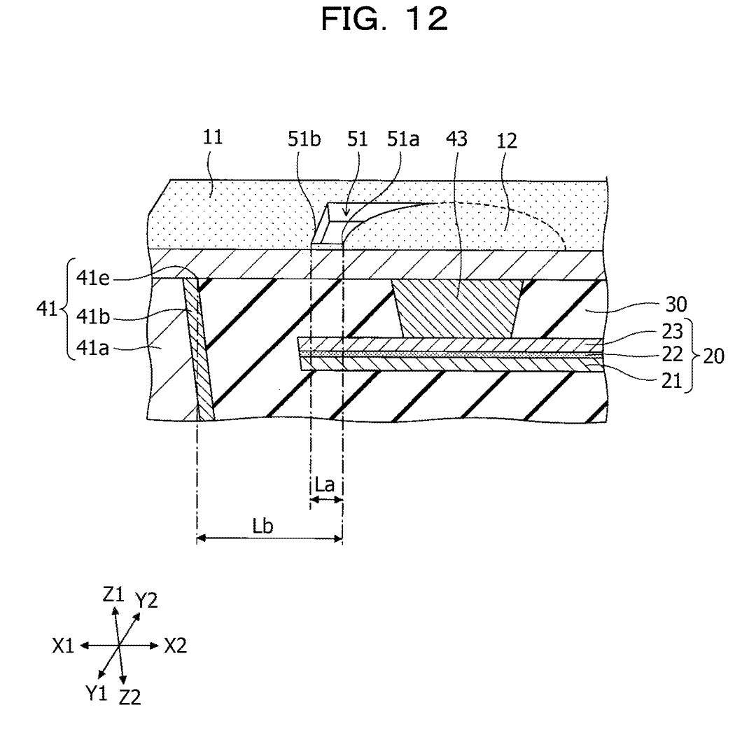

Next, with reference to FIG. 11, description is given of a value of stress (stress at the interlayer via bottom) in the portion in contact with the insulator layer 30 that is the connection portion between the thin-film capacitor 20 and the interlayer via 43 when the interlayer via pad-opening end distance La is changed. FIG. 11 illustrates a relationship between (interlayer via pad-opening end distance La)/(interlayer via pad-through-hole via end distance Lb) and the stress in the portion in contact with the insulator layer 30 that is the connection portion between the thin-film capacitor 20 and the interlayer via 43. As illustrated in FIG. 12, (interlayer via pad-opening end distance La) is a length from the position 51a where the interlayer via pad 12 and the connector 14 come into contact with each other, or the like to the end portion 51b of the opening 51 or the like on the X1 side. Likewise, (interlayer via pad-through-hole via end distance Lb) is a length from the position 51a where the interlayer via pad 12 and the connector 14 come into contact with each other, or the like to the end 41e on the X2 side of the through-hole via 41 on the X1 side.

As illustrated in FIG. 11, the larger the value of (interlayer via pad-opening end distance La)/(interlayer via pad-through-hole via end distance Lb), the smaller the stress at the interlayer via bottom. Therefore, (interlayer via pad-opening end distance La)/(interlayer via pad-through-hole via end distance Lb) preferably has a large value. As is clear from FIG. 11, when (interlayer via pad-opening end distance La)/(interlayer via pad-through-hole via end distance Lb) is 0.4 or more, the stress at the interlayer via bottom is 30 MPa or less, which is preferable. For example, the distance between the interlayer via pad 12 and the ends 51b and 52b of the openings 51 and 52 on the through-hole via 41 side relative to the distance between the interlayer via pad 12 and the through-hole via 41 is preferably 0.4 or more.

When (interlayer via pad-opening end distance La)/(interlayer via pad-through-hole via end distance Lb) has a value of 0.7 or more, the stress at the interlayer via bottom is 15 MPa or less, which is more preferable. When (interlayer via pad-opening end distance La)/(interlayer via pad-through-hole via end distance Lb) has a value around 0.4, the stress at the interlayer via bottom is locally reduced. This state is the state illustrated in FIG. 7, in which the end portions 51b and 52b of the openings 51 and 52 on the X1 side are approximately aligned with the end of the thin-film capacitor 20 on the X1 side. Therefore, it is inferred that, the stress is further relaxed in the circuit board when the ends of the openings 51 and 52 on the X1 side are aligned with the end of the thin-film capacitor 20 on the X1 side.

### Modified Example

Although the above description is given of the circuit board having the thin-film capacitor 20 formed therein, the circuit board according to this embodiment may include an electronic component other than the capacitor.

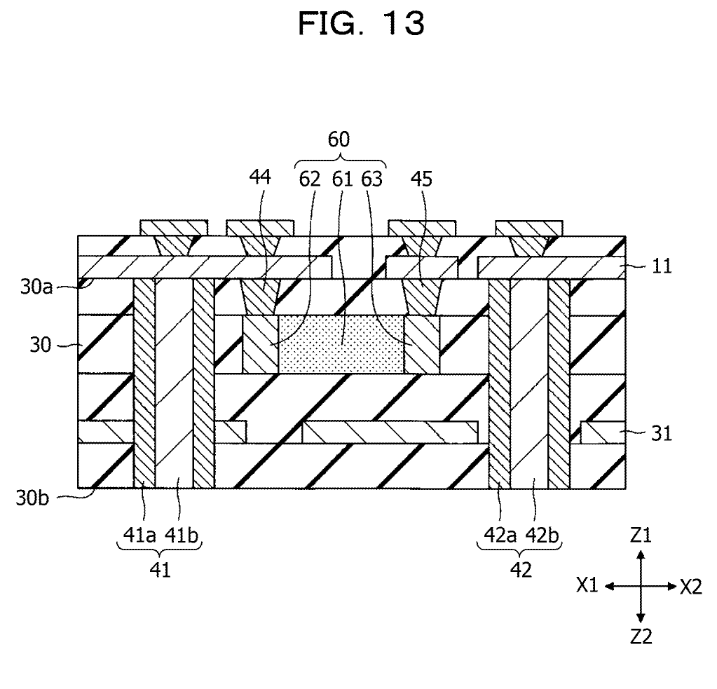

For example, the circuit board according to this embodiment may have a resistor 60 formed therein, as illustrated in FIG. 13, as an electronic component that serves as a passive element component. The resistor 60 has a structure in which electrodes 62 and 63 are formed on both sides of a resistive element 61 formed of a tantalum nitride thin film. One electrode 62 of the resistor 60 is connected to an interlayer via 44, while the other electrode 63 is connected to an interlayer via 45.

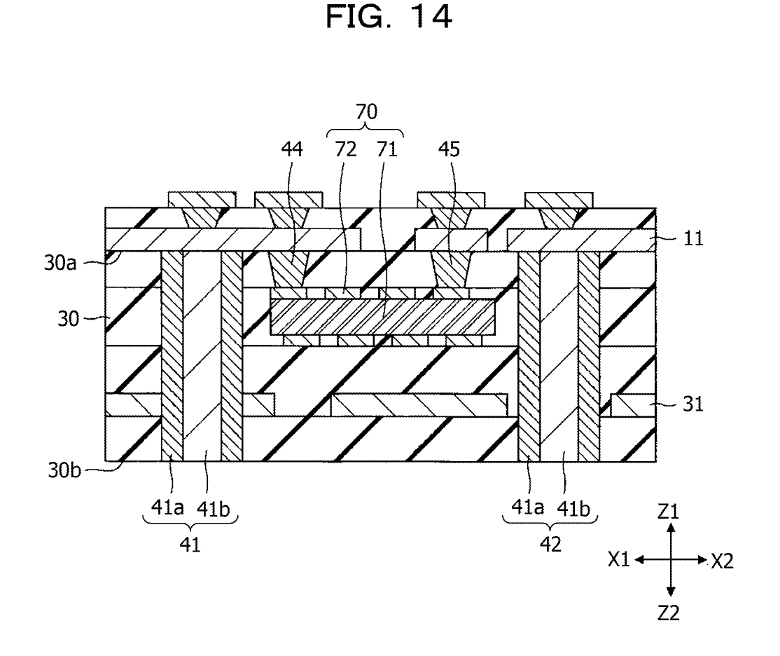

Alternatively, the circuit board according to this embodiment may have an inductor 70 formed therein, as illustrated in FIG. 14, as an electronic component that serves as a passive element component. The inductor 70 has a structure in which a metal wiring 72 is wound around a magnetic body 71 formed of ferrite or the like. One end of the metal wiring 72 in the inductor 70 is connected to an interlayer via 44, while the other end is connected to an interlayer via 45.

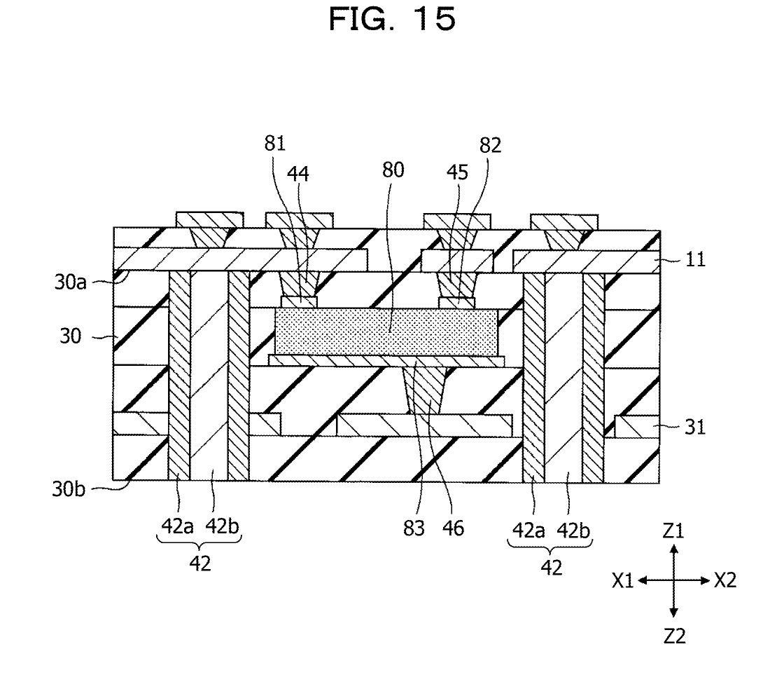

Alternatively, the circuit board according to this embodiment may have an integrated circuit 80 such as an IC formed therein, as illustrated in FIG. 15, as an electronic component that serves as an active element component. The integrated circuit 80 includes electrodes 81, 82, and 83. The electrode 81 of the integrated circuit 80 is connected to an interlayer via 44, the electrode 82 is connected to an interlayer via 45, and the electrode 83 is connected to an interlayer via 46.

### Second Embodiment

Next, a circuit board according to a second embodiment is described. The circuit board according to this embodiment has a structure in which the connector in the circuit board according to the first embodiment is not formed.

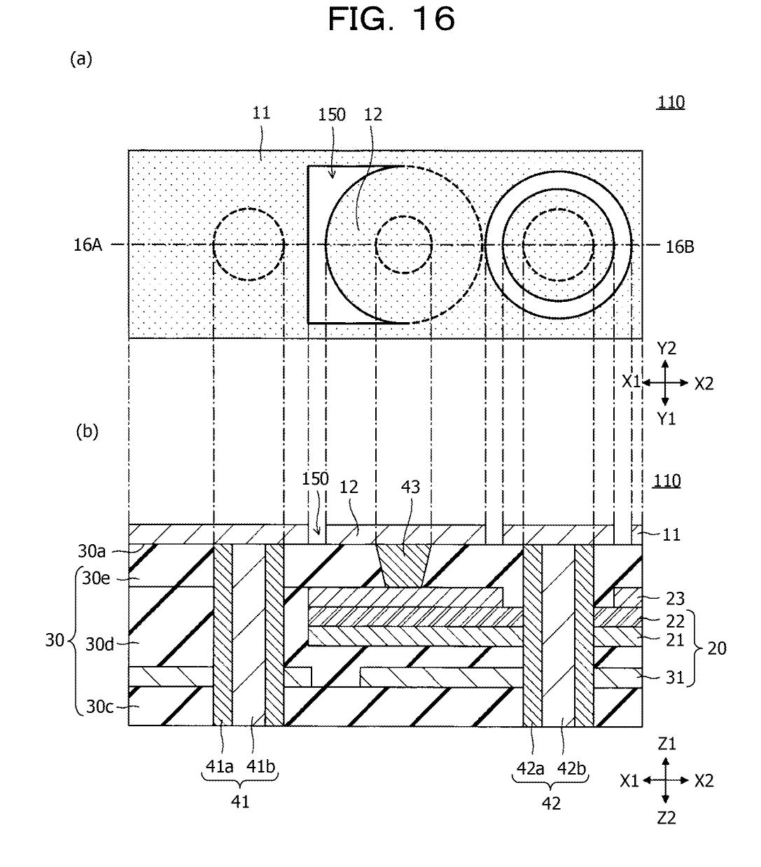

A circuit board 110 according to this embodiment has a structure, as illustrated in FIG. 16, in which a connector that connects an interlayer via pad 12 to a metal layer 11 is not formed but an opening 150 is formed on the X1 side of the interlayer via pad 12. FIG. 16(a) is a top view of the circuit board 110 according to this embodiment, while FIG. 16(b) is a cross-sectional view taken along the dashed line XVIA-XVIB.

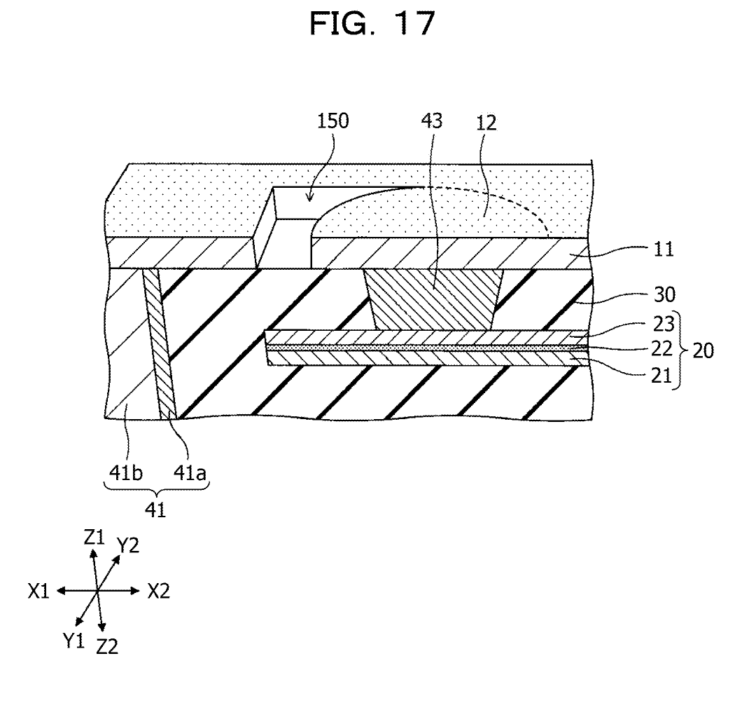

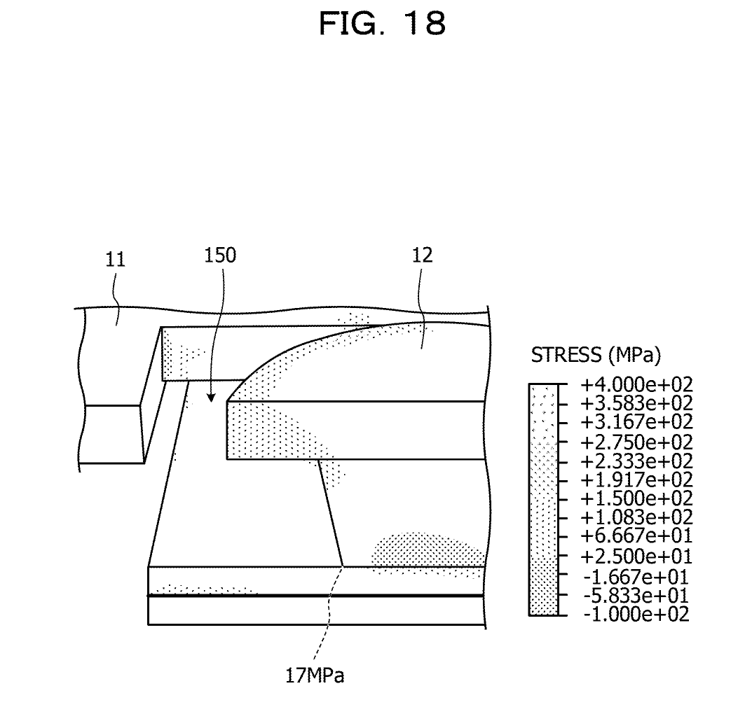

Next, FIG. 18 illustrates a result of simulation conducted on a circuit board model having a structure illustrated in FIG. 17, as a model of the circuit board 110 according to this embodiment. The model having the structure illustrated in FIG. 17 is a part of the circuit board 110 according to this embodiment illustrated in FIG. 16.

In the circuit board model illustrated in FIG. 17, the interlayer via pad 12 is in contact and integrated with the metal layer 11 on the X2 side, and the opening 150 is formed on the X1 side. The opening 150 is a region surrounded by a tangent to the interlayer via pad 12 on the Y1 side, which is parallel to the X1-X2 direction on the Y1 side, a part of the circumference of the interlayer via pad 12 on the X2 side, a tangent to the interlayer via pad 12 on the Y2 side, which is parallel to the X1-X2 direction on the Y2 side, and an end portion on the X1 side, which is parallel to the Y1-Y2 direction.

In the circuit board model illustrated in FIG. 17, when the temperature is raised from 25° C. to 250° C., a portion in contact with the insulator layer 30 that is a connection portion between the thin-film capacitor 20 and the interlayer via 43 has a stress value of 17 MPa as illustrated in FIG. 18.

Therefore, the circuit board according to this embodiment may achieve the same effect as that achieved by the circuit board according to the first embodiment.

### Method of Manufacturing Circuit Board

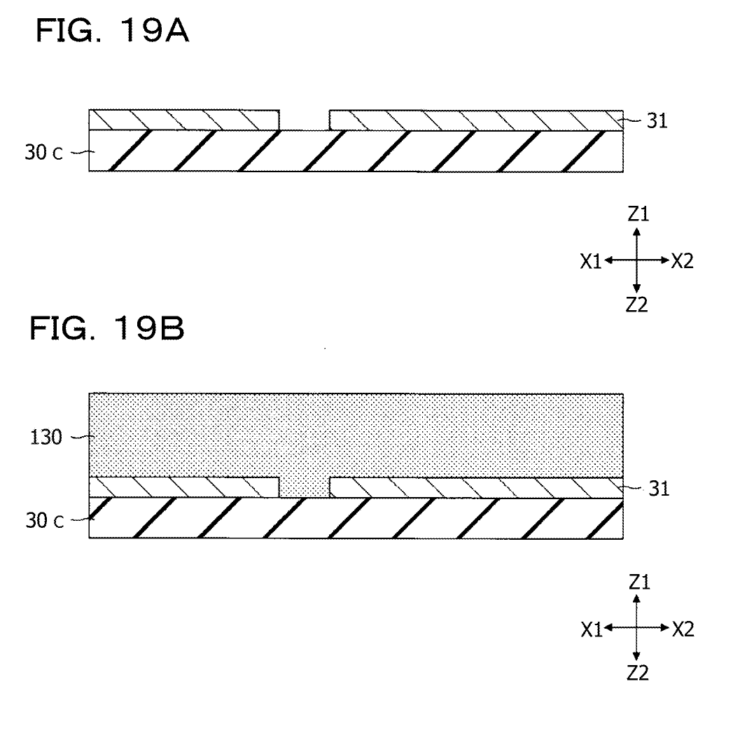

Next, with reference to FIGS. 19A to 23B, description is given of a method of manufacturing a circuit board according to this embodiment. For convenience, a structure of an electronic circuit in the following description is partially different from the structure illustrated in FIG. 16.

First, as illustrated in FIG. 19A, a wiring layer 31 having a desired pattern is formed on a core resin layer 30c. For example, a photoresist is applied onto a metal film formed on one surface of the core resin layer 30c, and the photoresist is exposed and developed by an exposure apparatus to form an unillustrated resist pattern on a region where the wiring layer 31 is formed. Thereafter, the metal film in a region where the resist pattern is not formed is removed by dry etching such as reactive ion etching (RIE) to expose the one surface of the core resin layer 30c, thereby forming the wiring layer 31. Subsequently, the unillustrated resist pattern is removed with an organic solvent or the like. The core resin layer 30c is formed of a resin material such as glass epoxy, polyimide, and bismaleimide triazine, for example. The wiring layer 31 is formed of a conductive metal material such as Cu.

Next, as illustrated in FIG. 19B, an uncured resin sheet 130 to form a first build-up resin layer 30d is stacked on the core resin layer 30c and the wiring layer 31. The first build-up resin layer 30d is formed of a resin material such as glass epoxy, polyimide, and bismaleimide triazine, for example.

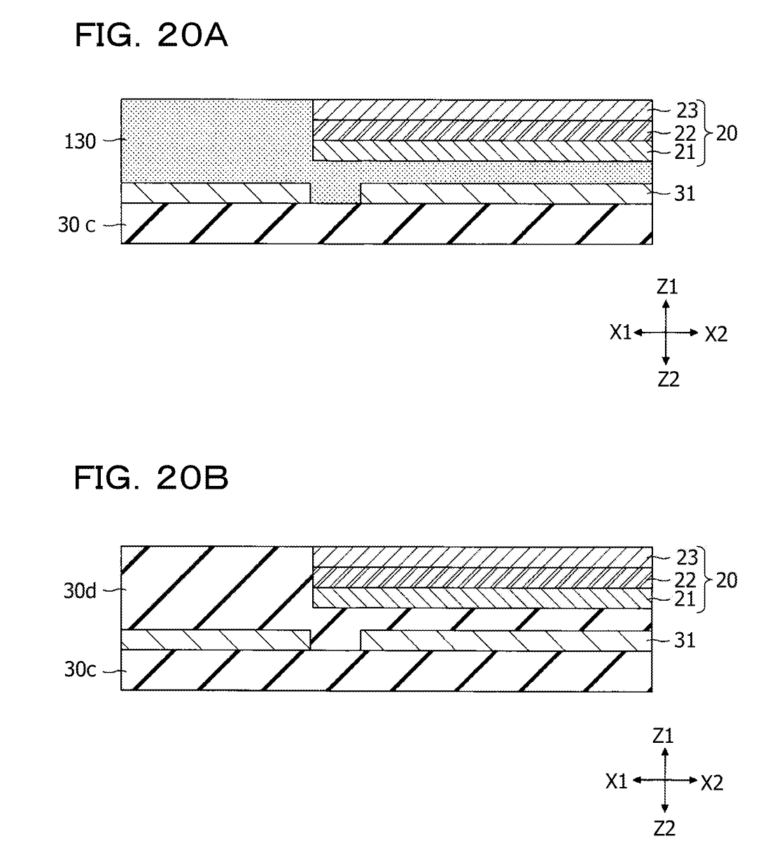

Then, as illustrated in FIG. 20A, a thin-film capacitor 20 is placed in a predetermined region of the resin sheet 130. For example, in the resin sheet 130, a thin-film capacitor piece is placed, including a Cu film having a film thickness of about 30 μm to be a lower electrode layer 21, a ferroelectric film having a film thickness of about 1 μm to be a ferroelectric layer 22, and an Ni film having a film thickness of about 30 μm to be an upper electrode layer 23. Thereafter, as illustrated in FIG. 20B, the resin sheet 130 is cured by heating to form the first build-up resin layer 30d. The ferroelectric layer 22 is formed of, for example, a ferroelectric ceramic material such as barium strontium titanate.

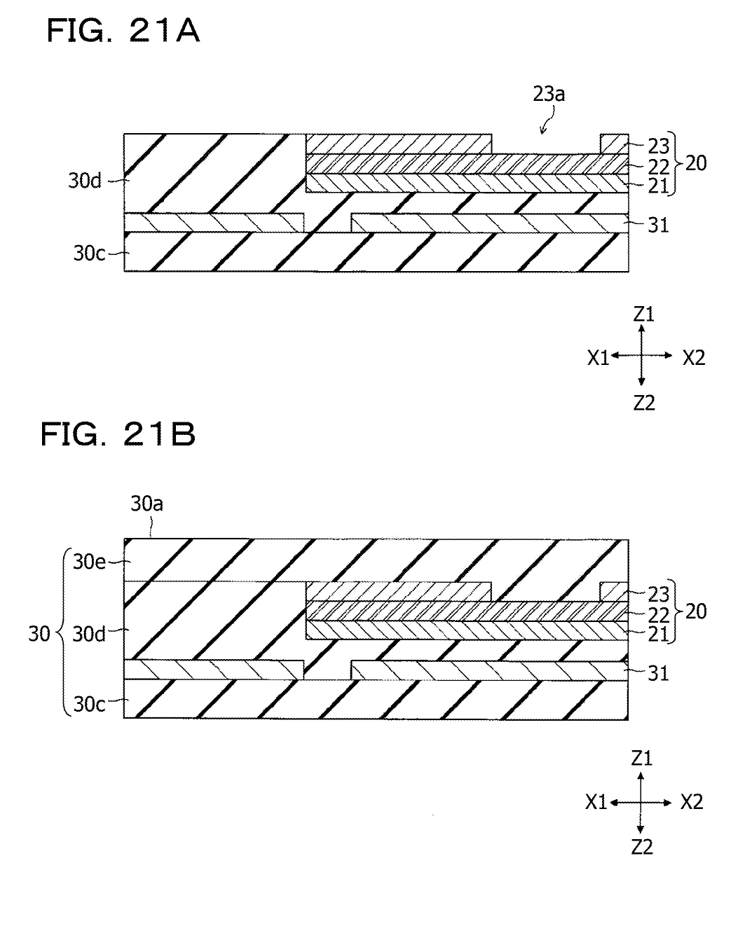

Next, as illustrated in FIG. 21A, an opening 23a is formed by removing a part of the upper electrode layer 23. For example, a photoresist is applied onto the upper electrode layer 23, the first build-up resin layer 30d, and the like, and the photoresist is exposed and developed by the exposure apparatus to form an unillustrated resist pattern having an opening in a region where the opening 23a is formed. Thereafter, the upper electrode layer 23 exposed in the opening of the resist pattern is removed by dry etching such as RIE. Subsequently, the unillustrated resist pattern is removed with an organic solvent or the like.

Then, as illustrated in FIG. 21B, an uncured resin sheet is stacked on the thin-film capacitor 20 and the first build-up resin layer 30d, and the resin sheet is cured by heating to form a second build-up resin layer 30e. The second build-up resin layer 30e is formed of, for example, a resin material such as glass epoxy, polyimide, and bismaleimide triazine. In this embodiment, the core resin layer 30c, the first build-up resin layer 30d, and the second build-up resin layer 30e form an insulator layer 30.

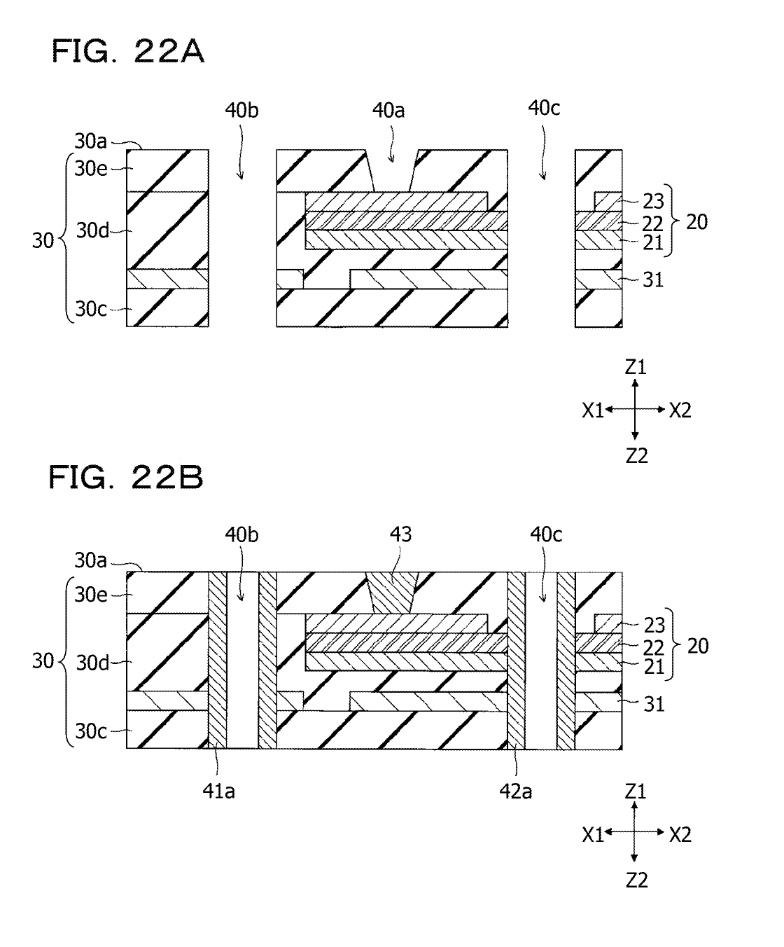

Thereafter, as illustrated in FIG. 22A, an opening hole 40a, in which the upper electrode layer 23 is exposed at the bottom, and through-holes 40b and 40c that penetrate from the top surface to the bottom surface of the insulator layer 30 are formed. The opening hole 40a is formed by removing the second build-up resin layer 30e with a laser and exposing the upper electrode layer 23. Examples of the laser used in this event include a carbon dioxide laser, an excimer laser, an ultraviolet (UV) laser, an yttrium aluminum garnet (YAG) laser, and the like. The through-holes 40b and 40c are formed by removing the insulator layer 30, the wiring layer 31, and the thin-film capacitor 20 with a drill or the like for total penetration. The opening hole 40a is formed to have a diameter of about 50 μm on the bottom surface side and to have a diameter of about 60 μm on the top surface side. The through-holes 40b and 40c are formed to have a diameter of about 60 μm.

Subsequently, as illustrated in FIG. 22B, an interlayer via 43 is formed by burying metal in the opening hole 40a by plating. Penetrating electrode layers 41a and 42a of through-hole vias 41 and 42 are formed by depositing metal films on inner walls of the through-holes 40b and 40c. These layers are formed, for example, by copper electroless plating. The penetrating electrode layers 41a and 42a formed on the inner walls of the through-holes 40b and 40c have a thickness of about 50 μm.

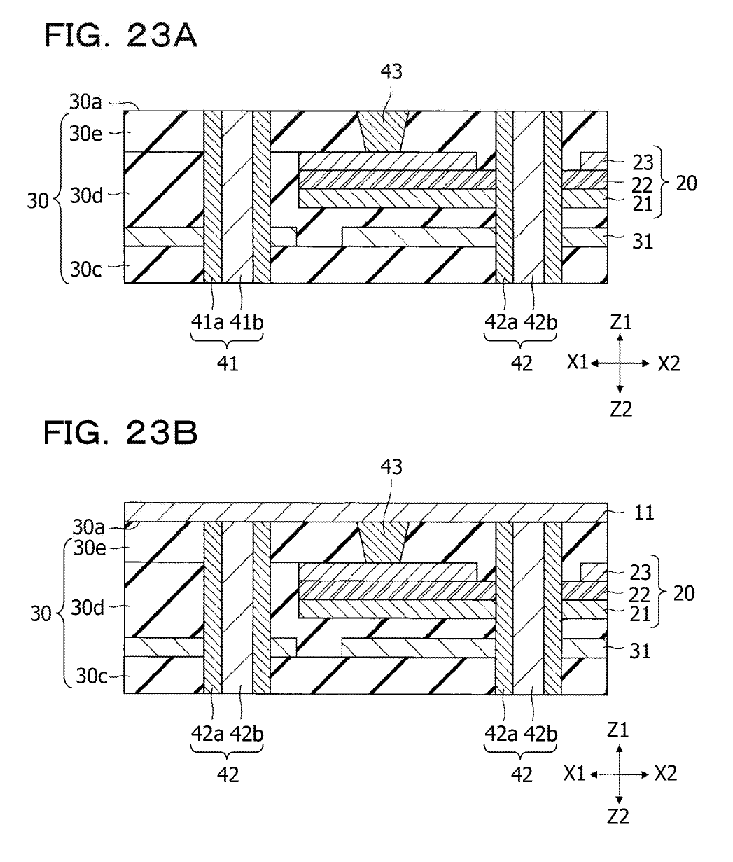

Next, as illustrated in FIG. 23A, a filler resin 41b is buried inside the penetrating electrode layer 41a to form the through-hole via 41, and a filler resin 42b is buried inside the penetrating electrode layer 42a to form the through-hole via 42.

Then, as illustrated in FIG. 23B, a metal layer 11 is formed by Cu electroless plating on one surface 30a of the insulator layer 30, that is, on the second build-up resin layer 30e to form the insulator layer 30 and the interlayer via 43.

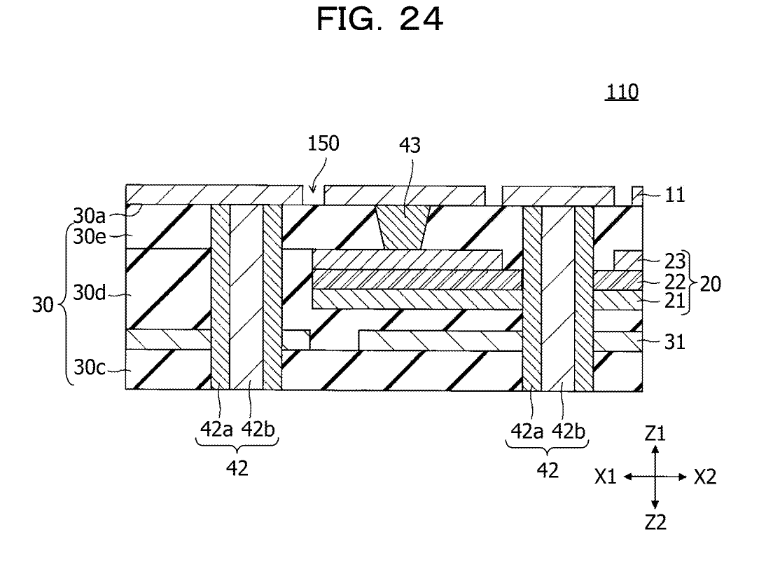

Thereafter, as illustrated in FIG. 24, the metal layer 11 is partially removed to form an opening 150 and a wiring pattern.

Through the above steps, the circuit board according to this embodiment may be manufactured. The circuit board according to the first embodiment may also be manufactured using the same manufacturing method as described above. The contents other than the above are the same as those in the first embodiment.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A circuit board comprising:
an insulator layer;
an electronic component built into the insulator layer;
a first via penetrating the insulator layer;
a second via extending from one surface of the insulator layer and coupled to the electronic component; and
a metal layer formed over the one surface of the insulator layer,
wherein a via pad is formed over the second via, an opening is formed between the metal layer and a first via side of the via pad, and
the opposite side of the via pad to the first via side is coupled to the metal layer.

2. The circuit board according to claim 1, further comprising
a plurality of openings.

3. The circuit board according to claim 1,
wherein a distance between the via pad and a first via side end of the opening relative to a distance between the via pad and the first via is 0.4 or more.

4. The circuit board according to claim 1,
wherein the electronic component is any of a capacitor, a resistor, an inductor, and an integrated circuit.

5. The circuit board according to claim 1,
wherein the electronic component is a capacitor in which a lower electrode layer, a ferroelectric layer, and an upper electrode layer are stacked.

6. A method of manufacturing a circuit board, comprising:
forming an electronic component over a first resin layer;
forming a second resin layer covering the first resin layer and the electronic component;
forming a first via penetrating the stacked first and second resin layers;
forming a second via coupled to the electronic component on the side where the second resin layer is formed; and
forming a metal layer over the second resin layer,
wherein a via pad is formed of a part of the metal layer formed over the second via, and an opening is formed in the metal layer between the via pad and the first via.
